(19) United States
(12) Patent Application Publication
(10) Pub. No.: US 2025/0072030 A1
(43) Pub. Date: Feb. 27, 2025

(54) DEVICE AND FORMATION METHOD THEREOF

(71) Applicants: TAIWAN SEMICONDUCTOR MANUFACTURING COMPANY, LTD., Hsinchu (TW); National Yang Ming Chiao Tung University, Hsinchu City (TW)

(72) Inventors: Yu-Rui CHEN, Taichung City (TW); Zefu ZHAO, Taipei City (TW); Yun-Wen CHEN, New Taipei City (TW); Chee-Wee LIU, Taipei City (TW)

(73) Assignees: TAIWAN SEMICONDUCTOR MANUFACTURING COMPANY, LTD., Hsinchu (TW); National Yang Ming Chiao Tung University, Hsinchu City (TW)

(21) Appl. No.: 18/454,546

(22) Filed: Aug. 23, 2023

(51) Int. Cl. H01L 29/66; H01L 29/51; H01L 29/78

(52) U.S. Cl. CPC H01L 29/6684; H01L 29/516; H01L 29/78391

(57) ABSTRACT

A device includes a substrate, a semiconductor layer and a ferroelectric layer. The semiconductor layer is over the substrate. The semiconductor layer is a single crystal silicon layer or a single crystal germanium layer. The ferroelectric layer is over the semiconductor layer. The ferroelectric layer is in physical contact with the semiconductor layer and has an orthorhombic phase.

### BACKGROUND

The semiconductor integrated circuit (IC) industry has experienced rapid growth. In the course of IC evolution, functional density (i.e., the number of interconnected devices per chip area) has increased while geometry size (i.e., the smallest component (or line) that can be created using a fabrication process) has decreased. This scaling down process increases production efficiency and lowers associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3A, 3B, 3C and 3D are cross-sectional views of forming an epitaxial structure in accordance with some embodiments.

FIG. 4A is a sheet of lattice constants of the ferroelectric layer with an orthorhombic phase (o-phase), a tetragonal phase (t-phase), a monoclinic phase (m-phase) in accordance with some embodiments.

FIG. 4B is a sheet of lattice constant of the semiconductor layer and lattice misfit at an interface between the semiconductor layer and the ferroelectric layer.

FIG. 5 is a graph of interfacial energies between the semiconductor layer and the ferroelectric layer with o-phase in accordance with examples and comparative examples.

FIG. 6A is a figurative diagram of lattice mismatched formation of the ferroelectric layer of ZrO₂ with o-phase formed on the semiconductor layer of silicon and germanium in accordance with some embodiments.

FIG. 6B is a figurative diagram of lattice mismatched formation of a comparable example including an ZrO₂ layer with m-phase formed on a silicon layer and a germanium layer.

FIG. 6C is a figurative diagram of lattice mismatched formation of a comparable example including an ZrO₂ layer with t-phase formed on a silicon layer and a germanium layer.

FIG. 7A is a chart of a polarization-voltage (P-V) hysteresis loop with respect to an example of the epitaxial structure in FIG. 3A where the semiconductor layer is made of single crystal silicon and the ferroelectric layer is made of HZO, such as Hf_{0.5}Zr_{0.5}O₂.

FIG. 7B is a chart of a polarization-voltage (P-V) hysteresis loop with respect to an example of the epitaxial structure in FIG. 3A where the semiconductor layer is made of single crystal germanium and the ferroelectric layer is made of HZO, such as Hf_{0.5}Zr_{0.5}O₂.

FIG. 8 is a diagram of remanent polarization (2Pr) versus thickness in accordance with examples and comparative examples.

FIGS. 9-12 are example methods of forming a ferroelectric layer in accordance with some embodiments.

FIG. 13A is a cross-sectional view of forming an epitaxial structure in accordance with some embodiments.

FIG. 13B is a cross-sectional view of a semiconductor device in accordance with some embodiments.

FIGS. 14 and 15A are cross-sectional views of forming an epitaxial structure in accordance with some embodiments.

FIG. 15B is a cross-sectional view of a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated.

A ferroelectric (FE) material is a dielectric that exhibits a spontaneous electric polarization. The direction of spontaneous polarization can be reversed between two crystallographic defined states by application of an external electric field. The ferroelectric material can thus offer an electrically switchable, tow-state device. The ferroelectric material exhibits a remnant polarization defined as an amount of polarization that remains in the ferroelectric material after an electric field is removed, which allows the ferroelectric material to function as a non-volatile memory. However, the ferroelectric material formed on an amorphous or polycrystalline interfacial layer, which separated the substrate the ferroelectric material, may have a low remnant polarization.

Embodiments such as those described herein provide a negative capacitance (NC), which can be utilized in forming negative capacitance gate stacks to allow formation of field effect transistor (FET) devices, such as planar FET, FinFET, or gate all around FET (GAAFET). Embodiments of the present disclosure relate to forming a ferroelectric layer on a single crystal underlayer such that the ferroelectric layer has low lattice misfit at an interface between the ferroelectric layer and the single crystal underlayer. For example, the ferroelectric layer can be single crystalline or very close to single crystalline (i.e., having a crystallinity greater than about 80%). Therefore, the ferroelectric layer can have high remnant polarization and high uniformity, in which the high uniformity is important for integrated circuit applications.

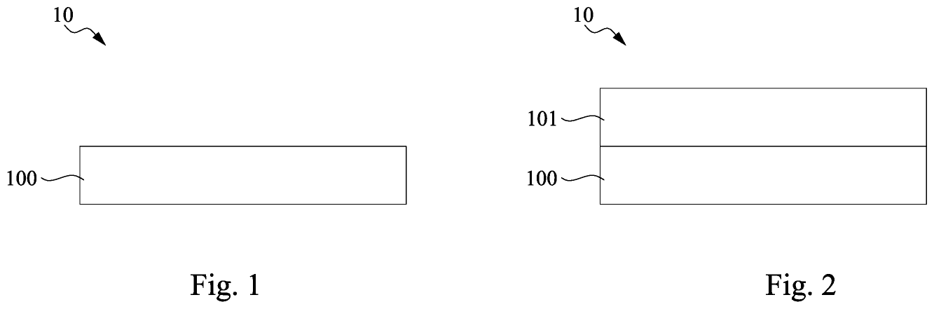

FIGS. 1, 2, 3A, 3B, 3C, 3D and 13A are cross-sectional views of forming an epitaxial structure 10 in accordance with some embodiments. Reference is made to FIG. 1. In some embodiments, a substrate 100 is provided. In some embodiments, the epitaxial structure 10 can be referred to as a semiconductor structure. The substrate 100 is configured to provide mechanical and structural support during subsequent processing step. For example, the substrate 100 can support formation of a subsequently formed single crystal layer. The substrate 100 can thus be referred to as a support substrate. In some embodiments, the substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Next, a cleaning may be performed to remove a native oxide formed on a surface of the substrate 100. The cleaning may be performed using diluted hydrofluoric (HF) acid, for example. Reference is then made to FIG. 2. A semiconductor layer 101 is formed on the substrate 100, and includes a crystalline material. In certain embodiments, the semiconductor layer 101 includes a single crystal structure which may be doped (e.g., with a p-type or an n-type dopant) or undoped. In some embodiments, the semiconductor layer 101 may include heavily doped silicon, germanium, Si₁₋ₓGeₓ, or any other materials with a low lattice misfit to a subsequently formed overlying layer with a first crystal phase, which will be discussed later in greater detail. In some embodiments, the semiconductor layer 101 is formed by an epitaxy growth using a suitable deposition process, such as atomic layer deposition (ALD), chemical vapor deposition (CVD), molecular beam epitaxy (MBE), physical vapor deposition (PVD), or the like.

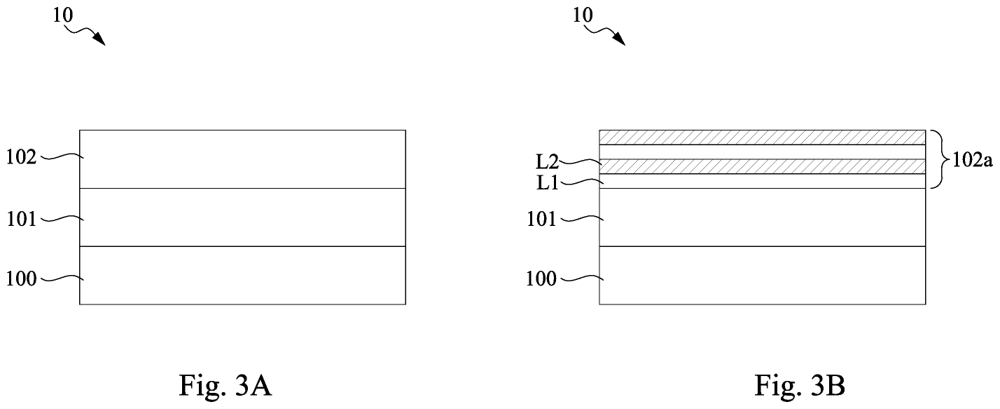

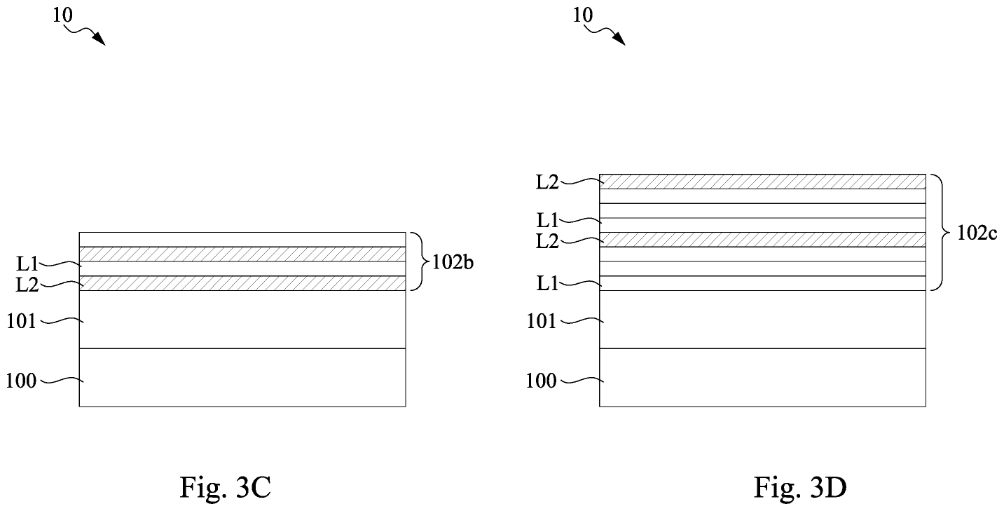

Reference is made to FIG. 3A. In some embodiments, a ferroelectric layer 102 is formed on the semiconductor layer 101, and includes a crystalline material. In some embodiments, the ferroelectric layer 102 is an epitaxial ferroelectric layer formed by an epitaxy growth using a suitable deposition process, such as ALD. In some other embodiments, the ferroelectric layer 102 may be formed using CVD, MBE, PVD, or the like. In some embodiments, the ferroelectric layer 102 is made of a second ferroelectric material having a composition different from a composition of the first ferroelectric material, and the first ferroelectric material has a phase same as a phase of the second ferroelectric material, such as the orthorhombic phase. In some embodiments, the ferroelectric layer 102 includes HZO. For example, the ferroelectric layer 102 may be an HfₓZr₁₋ₓO₂ layer in which x is greater than zero and less than or equal to about 0.5. In some embodiments, the ferroelectric layer 102 has a thickness in a range from about 1 nm to about 20 nm.

Reference is made to FIG. 3B. In some embodiments, the ferroelectric layer 102 is a supper lattice structure or an alloy, such as a supper lattice structure made of alternately stacked first oxide films and second oxide films, and the first oxide films have a composition different from a composition of the second oxide films. In some embodiments, the ferroelectric layer 102 is made of a plurality of first oxide films and a plurality of second oxide films, and the first oxide films have a composition different from a composition of the second oxide films. In some embodiments, the ferroelectric layer 102 is an HfO₂-ZrO₂ supper lattice or an HfO₂-ZrO₂ alloy. For example, a ferroelectric layer 102a includes a plurality HfO₂ films L1 and a plurality of ZrO₂ films L2 alternately stacked over the semiconductor layer 101. Each of the plurality of HfO₂ films L1 may be formed by one or more HfO₂ monolayers. Similarly, each of the plurality of ZrO₂ films L2 may be formed by one or more ZrO₂ monolayers. A bottommost one of the plurality of the HfO₂ films L1 is in contact with the semiconductor layer 101. In FIG. 3C, in some other embodiments, a bottommost one of the ZrO₂ films L2 in the ferroelectric layer 102b is in contact with the semiconductor layer 101. It should be noted that the number of the HfO₂ films L1 and the number of the ZrO₂ films L2 may be greater than two or more than two; the disclosure is not limited thereto. In certain embodiments, a number of the HfO₂ films L1 is greater than a number of the ZrO₂ films L2, which will be discussed later in greater detail.

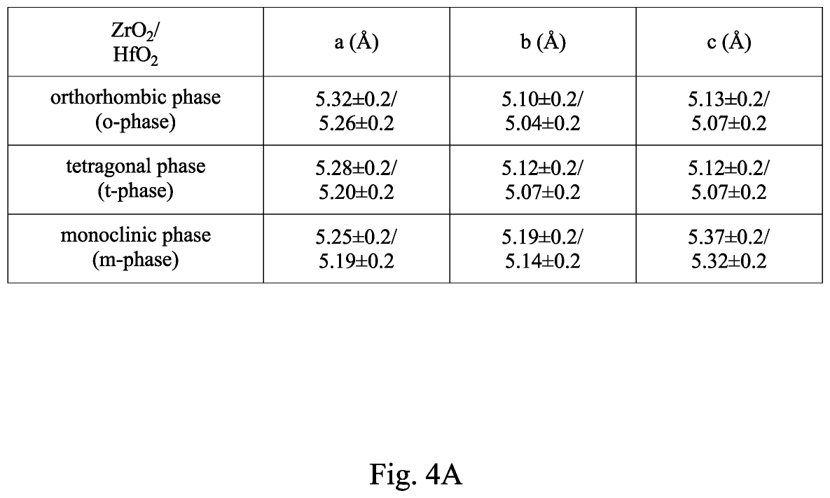

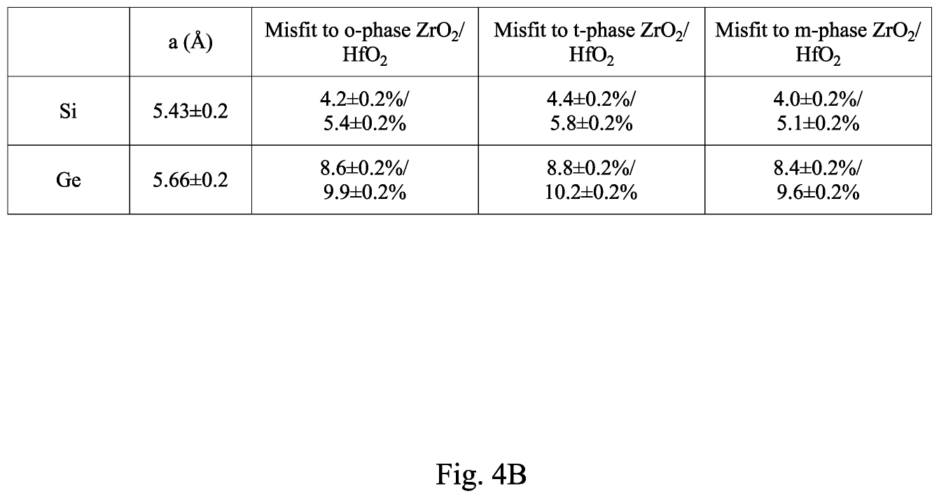

FIG. 4A is a sheet of lattice constants of the ferroelectric layer 102 with an orthorhombic phase (o-phase), a tetragonal phase (t-phase), a monoclinic phase (m-phase) in accordance with some embodiments. FIG. 4B is a sheet of lattice constant of the semiconductor layer 101 and lattice misfit at an interface between the semiconductor layer 101 and the ferroelectric layer 102. In some embodiments, the ferroelectric layer 102 and the semiconductor layer 101 have different phases. In other words, the ferroelectric layer 102 and the semiconductor layer 101 have different crystal structures. Reference is made to FIG. 4A. In some embodiments, in the o-phase of the ZrO₂, axial lengths are, for example, a=5.32±0.2 Å, b=5.10±0.2 Å, and c=5.13±0.2 Å. In some embodiments, in the o-phase of the HfO₂, axial lengths are, for example, a=5.26±0.2 Å, b=5.04±0.2 Å, and c=5.07±0.2 Å. By contrast, in the t-phase of the ZrO₂, axial lengths are, for example, a=5.28±0.2 Å, b=5.12±0.2 Å, and c=5.12±0.2 Å. In some embodiments, in the t-phase of the HfO₂, axial lengths are, for example, a=5.20±0.2 Å, b=5.07±0.2 Å, and c=5.07±0.2 Å. Also, by contrast, in the m-phase of the ZrO₂, axial lengths are, for example, a=5.25±0.2 Å, b=5.19±0.2 Å, and c=5.37±0.2 Å. In the m-phase of the HfO₂, axial lengths are, for example, a=5.19±0.2 Å, b=5.14±0.2 Å, and c=5.32±0.2 Å.

Reference is then made to FIGS. 3A and 4B. In certain embodiments, the semiconductor layer 101 is a silicon layer, such as a single crystal silicon layer with a cubic phase with an axial length, for example, a=5.43±0.2 Å. Therefore, the semiconductor layer 101 can have a low lattice misfit to the ferroelectric layer 102 made of H₂O with o-phase. For example, the semiconductor layer 101 has the lattice misfit being less than about 10% to both of the ZrO₂ with o-phase and the HfO₂ with o-phase. If the lattice misfit between the semiconductor layer 101 and the ferroelectric layer 102 is greater than about 10%, the ferroelectric layer 102 may have a reduced crystallinity, such as lower about 80%. For example, in some embodiments where the semiconductor layer 101 is single crystal silicon layer, the semiconductor layer 101 has a lattice misfit of about 4.2±0.2% to the ZrO₂ with the o-phase, and has a lattice misfit of about 5.4±0.2% to the HfO₂ with the o-phase. In certain embodiments, the semiconductor layer 101 is a germanium layer, such as a single crystal germanium layer with a cubic phase with an axial length, for example, a=5.66±0.2 Å. Therefore, the semiconductor layer 101 can have a low lattice misfit to the ferroelectric layer 102 made of HZO with o-phase. For example, in some embodiments where the semiconductor layer 101 is a single crystal germanium layer, the semiconductor layer 101 has a lattice misfit being less than about 10% to both of the ZrO₂ with o-phase and the HfO₂ with o-phase as well. For example, in some embodiments where the semiconductor layer 101 is single crystal germanium layer, the semiconductor layer 101 has a lattice misfit of about 8.6±0.2% to the ZrO₂ with the o-phase, and has a lattice misfit of about 9.9±0.2% to the HfO₂ with the o-phase.

The ferroelectric layer 102 is in physical contact with the semiconductor layer 101 in some embodiments. Since the ferroelectric layer 102 formed on the single crystal underlayer (e.g., the semiconductor layer 101 including the single crystal silicon layer or the single crystal germanium layer), the ferroelectric layer can have a low lattice misfit at an interface between the ferroelectric layer 102 and the single crystal underlayer. For example, the ferroelectric layer 102 can be single crystalline or very close to single crystalline (i.e., having a crystallinity greater than about 80%) on the semiconductor layer 101 without forming an interfacial layer between the ferroelectric layer 102 and the semiconductor layer 101. Therefore, the ferroelectric layer 102 can have high remnant polarization and high uniformity, in which the high uniformity is important for integrated circuit applications.

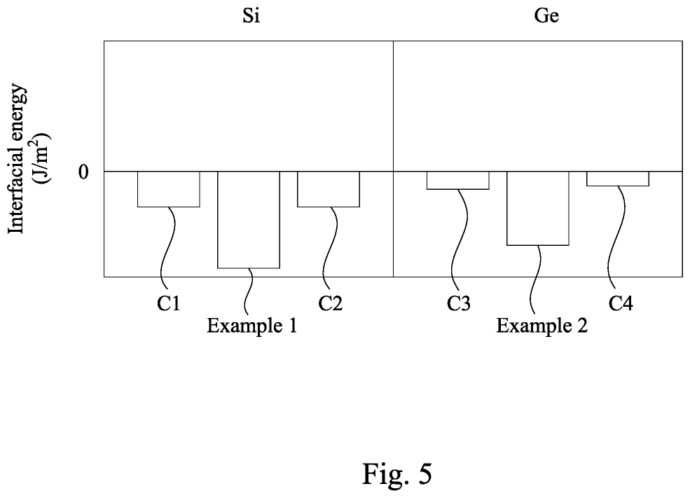

FIG. 5 is a graph of interfacial energies between the semiconductor layer 101 and the ferroelectric layer 102 with o-phase in accordance with examples and comparative examples C1, C2, C3 and C4. Reference is made to FIGS. 3A and 5. In an example 1 where the semiconductor layer 101 is silicon (Si), the semiconductor layer 101 and the ferroelectric layer 102 with o-phase has a lowest interfacial energy, such as in a range from about −2 eV to about −4 eV, such as −2.9 eV. By contrast, in the comparative example C1, a ferroelectric layer with m-phase is formed on a silicon layer. In the comparative example C2, a ferroelectric layer with t-phase is formed on a silicon layer. In the comparable example C1, the ferroelectric layer with m-phase formed on the silicon layer has an interfacial energy in a range from about −1.5 eV to about −0.5 eV, such as about −0.93 eV. In the comparable example C2, the ferroelectric layer with t-phase formed on the silicon layer has an interfacial energy in a range from about −1.5 eV to about −0.5 eV, such as about −0.97 eV. In an example 2 where the semiconductor layer 101 is germanium (Ge), the semiconductor layer 101 and the ferroelectric layer 102 with o-phase has a lowest interfacial energy, such as in a range from about −2.8 eV to about −1.6 eV, such as about −2.22 eV. By contrast, in the comparative example C3, a ferroelectric layer with m-phase is formed on a germanium layer. In the comparative example C4, a ferroelectric layer with t-phase is formed on a silicon layer. In the comparable example C3, the ferroelectric layer with m-phase formed on the germanium layer have an interfacial energy in a range from about −0.5 eV to about −1.5 eV, such as about −0.77 eV. In the comparable example C4, the ferroelectric layer with t-phase formed on the germanium layer have an interfacial energy in a range from about −0.2 eV to about −0.8 eV, such as about −0.56 eV. The low interfacial energy in the examples 1 and 2 indicate that the ferroelectric layer 102 can have a stabilized o-phase when the ferroelectric layer 102 is formed on the semiconductor layer 101 made of silicon or germanium. In some embodiments, the silicon-oxygen (Si—O) bonding energy is greater than germanium-oxygen (Ge-O) bonding energy since the interfacial energy in the example 1 is lower than the interfacial energy in the example 2.

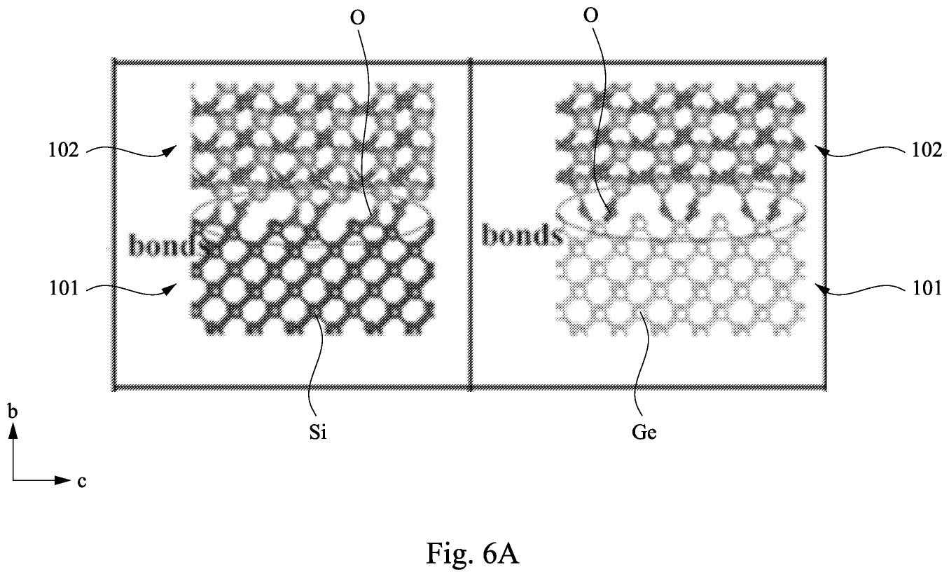

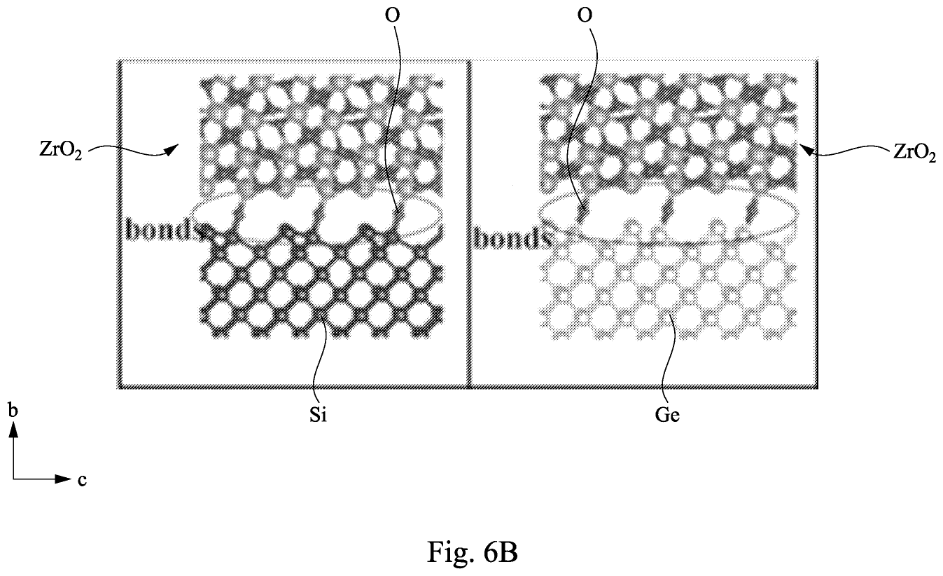

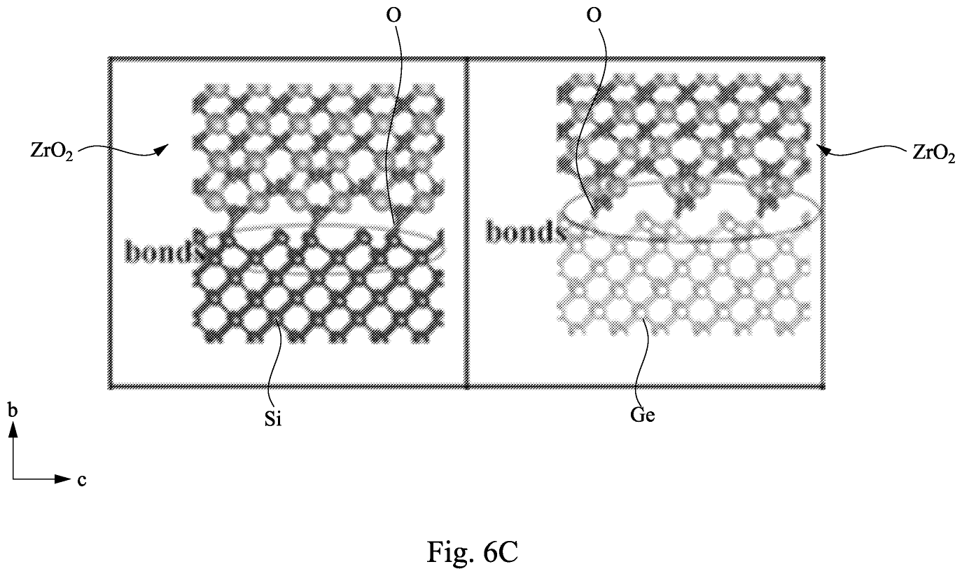

FIG. 6A is a figurative diagram of lattice mismatched formation of the ferroelectric layer 102 of ZrO₂ with o-phase formed on the semiconductor layer 101 of silicon and germanium in accordance with some embodiments. FIG. 6B is a figurative diagram of lattice mismatched formation of a comparable example including an HZO layer with m-phase formed on a silicon layer and a germanium layer. As can be seen, the silicon atoms (“Si”) of the silicon layer are bonded to the oxygen atoms (“O”) of the HZO. FIG. 6C is a figurative diagram of lattice mismatched formation of a comparable example including an ZrO₂ layer with t-phase formed on a silicon layer and a germanium layer. In FIG. 6A, a plurality of Si—O bonds and a plurality of Ge-O bonds are formed between the semiconductor layer 101 and the ferroelectric layer 102, respectively. For example, a number of the Si—O bonds is about 17 to 19, such as about 18. By contrast, in FIG. 6B, fewer Si—O bonds and fewer Ge-O bonds are formed between the ZrO₂ and the silicon and germanium, respectively. For example, each of a number of the Si—O bonds and a number of the Ge-O bonds is about 8 to 10, such as about 9. In FIG. 6C, fewer Si—O bonds and fewer Ge-O bonds are formed between the ZrO₂ and the silicon and germanium, respectively. For example, each of a number of the Si—O bonds and a number of the Ge-O bonds is about 8 to 10, such as about 9. The number of the bonds between two layers shows a negative correlation to the interfacial energy therebetween. The ferroelectric layer 102 with o-phase can have a low interfacial energy over the semiconductor layer 101 of silicon or germanium as compared to the ZrO₂ with m-phase and t-phase over the silicon or germanium.

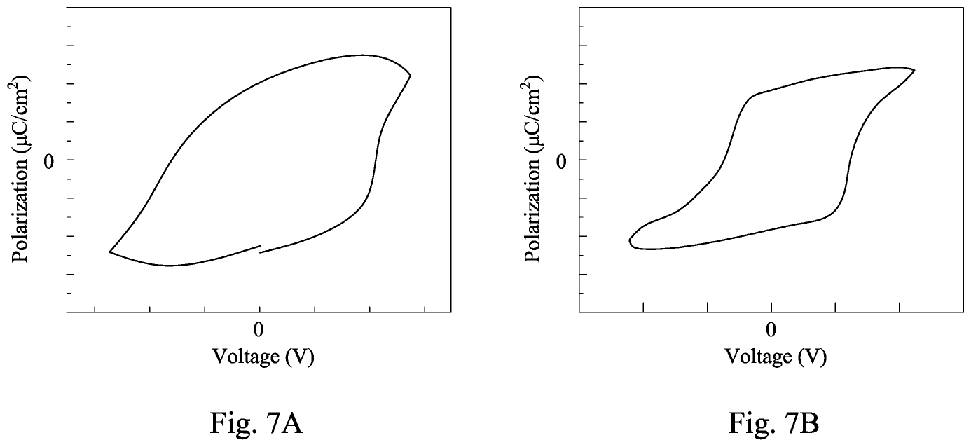

FIG. 7A is a chart of a polarization-voltage (P-V) hysteresis loop with respect to an example 3 of the epitaxial structure 10 in FIG. 3A where the semiconductor layer 101 is made of single crystal silicon and the ferroelectric layer 102 is made of HZO, such as Hf_{0.5}Zr_{0.5}O₂. Reference is made to FIGS. 3A and 7A. Due to the low lattice misfit between the HZO (e.g., the Hf_{0.5}Zr_{0.5}O₂) and the single crystal silicon, the ferroelectric layer 102 can be a single crystal layer or a crystalline layer with a crystallinity greater than about 80% such that the ferroelectric layer 102 has a high remanent polarization (2Pr). For example, the ferroelectric layer 102 has a remanent polarization in a range from about 50 μC/cm² to about 110 μC/cm², such as about 84 μC/cm². FIG. 7B is a chart of a polarization-voltage (P-V) hysteresis loop with respect to an example 4 of the epitaxial structure 10 in FIG. 3A where the semiconductor layer 101 is made of single crystal germanium and the ferroelectric layer 102 is made of HZO, such as Hf_{0.5}Zr_{0.5}O₂. Reference is made to FIGS. 3A and 7B. Due to the low lattice misfit between the HZO (e.g., the Hf_{0.5}Zr_{0.5}O₂) and the single crystal germanium, the ferroelectric layer 102 can be a single crystal layer or a crystalline layer with a crystallinity greater than about 80% such that the ferroelectric layer 102 has a high remanent polarization (2Pr). For example, the ferroelectric layer 102 has a remanent polarization in a range from about 50 μC/cm² to about 110 μC/cm², such as about 73 μC/cm².

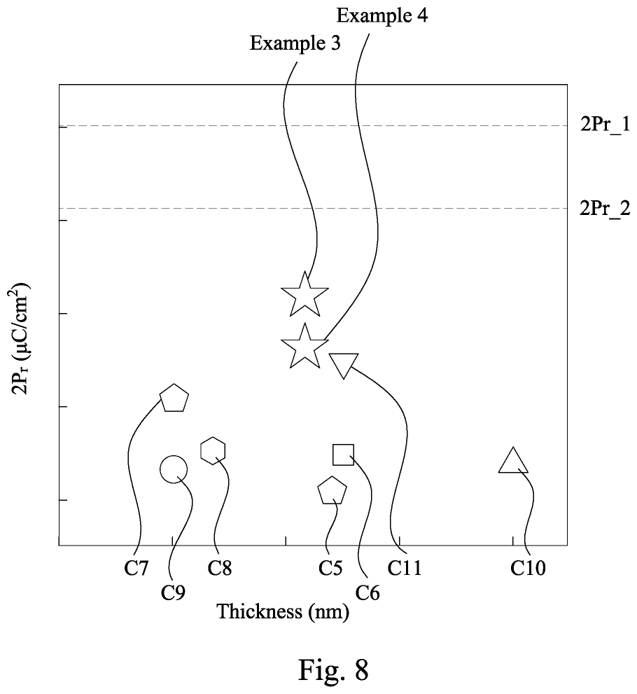

FIG. 8 is a diagram of remanent polarization (2Pr) versus thickness in accordance with examples 3 and 4 and comparative examples C5, C6, C7, C8, C9, C10 and C11. Reference is made to FIGS. 3A and 8. In some embodiments where the epitaxial structure 10 includes the ferroelectric layer 102 made of ZrO₂, the ferroelectric layer 102 has a theoretical remanent polarization 2Pr_1 in a range from about 110 μC/cm² to 130 μC/cm², such as about 120 μC/cm². In some embodiments where the epitaxial structure 10 includes the ferroelectric layer 102 made of HfO₂, the ferroelectric layer has a theoretical remanent polarization 2Pr_2 in a range from about 90 μC/cm² to about 110 μC/cm², such as about 102.6 μC/cm². The examples 3 and 4 show remanent polarizations nearest to the theoretical remanent polarizations 2Pr_1 and 2Pr_2.

In a comparative example C5, an HZO layer is formed on a titanium nitride layer. In a comparative example C6, an HZO layer is formed on an interfacial layer (IL) over a titanium nitride layer. In a comparative example C7, an HZO layer is formed on tungsten layer. In a comparative example C8, an HZO layer is formed on a titanium nitride layer. In a comparative example C9, an HZO layer is formed on an AlON layer over a silicon substrate doped with n-type dopants. In a comparative example C10, an HZO layer is formed on a Pt layer. In a comparative example C11, an HZO layer is formed on a titanium nitride layer. As shown in FIG. 8, the examples 3 and 4 have increased remanent polarizations greater than remanent polarizations of comparative examples C5, C6, C7, C8, C9, C10 and C11.

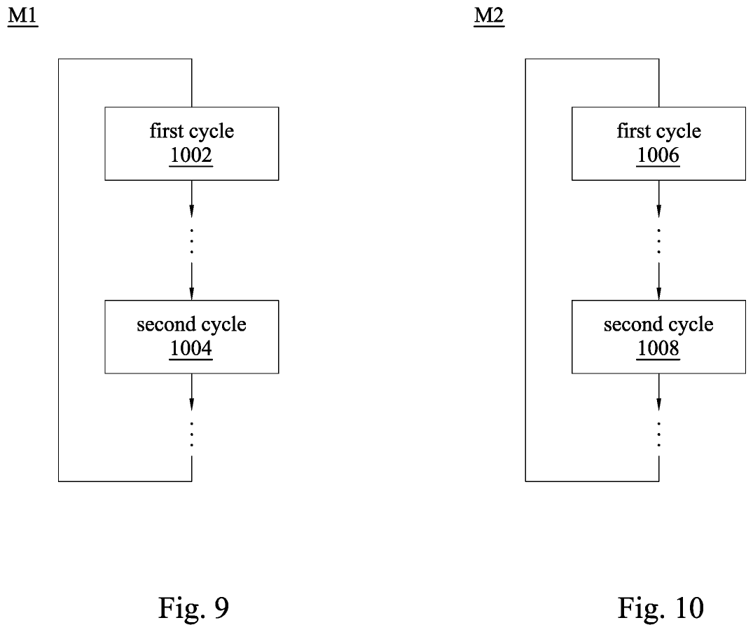

FIGS. 9-12 are example methods of forming a ferroelectric layer in accordance with some embodiments. Reference is made to FIGS. 3A and 9. In some embodiments where the ferroelectric layer 102 is formed by ALD process using a method M1, in which the method M1 may be thermal atomic layer deposition (thermal ALD) and includes one or more first cycles 1002 and one or more second cycles 1004. Each of the first cycles 1002 includes introducing a first precursor, purging the first precursor with a purge gas, introducing an oxidant and purging the first oxidant with a purge gas. In some embodiments, the first precursor includes Zr-containing precursor, and the oxidant includes oxygen, water, ozone, a combination thereof, or the like. The purge gas may be unreactive inert gas, such as Ar or N₂. In each of the first cycles 1002, the oxidant reacts with the first precursor, forming a monolayer of ZrOₓ. In some embodiments, the first cycles 1002 are repeated until a desired thickness is achieved. Each of the second cycles 1004 includes introducing a second precursor, purging the second precursor with a purge gas, introducing an oxidant and purging the oxidant with a purge gas. In some embodiments, the second precursor includes Hf-containing precursor, and the oxidant includes oxygen, water, ozone, a combination thereof, or the like. The purge gas may be unreactive inert gas, such as Ar or N₂. In each of the second cycles 1004, the oxidant reacts with the second precursor, forming a monolayer of HfOₓ. In some embodiments, the second cycles 1004 are repeated until a desired thickness is achieved. A sum of a number of the first cycles 1002 and a number of the second cycles 1004 can be referred to as a period. In some embodiments, a plurality of periods are performed to form the ferroelectric layer 102 such that the ferroelectric layer is a supper lattice structure or an alloy, such as an HfO₂-ZrO₂ supper lattice or an HfO₂-ZrO₂ alloy. In some embodiments, the number of the first cycles 1002 and the number of the second cycles 1004 are substantially the same. In certain embodiments, a ratio of the number of the first cycles 1002 and the number of the second cycles 1004 can be referred to as a first ratio.

Reference is made to FIGS. 3D and 10. In some embodiments, the ferroelectric layer 102c may be an HfOₓ (e.g., HfO₂) layer doped with dopants formed using a method M2. For example, the method M2 includes a first cycle 1006 and a second cycle 1008. The method M2 is similar to the method M1, except for a second ratio of a number to the first cycles 1006 to a number of the second cycles 1008 being greater than the first ratio between the first cycles 1002 and the second cycles 1004, and the second precursor in the second cycles 1008 including various materials. For example, the second ratio can be in a range from about 20 to about 40, such as about 30. As a result, the number or the first oxide films L1 is greater than the number of the second oxide films L2. In some embodiments, in the second cycles 1008 of the method M2, the second precursor may be Zr-containing precursor, Si-containing precursor, Sr-containing precursor, Y-containing precursor, La-containing precursor, Ge-containing precursor, Al-containing precursor, or the like. As such, the ferroelectric layer 102c may be a hafnium oxide layer doped with oxide layers of Zr, Si, Sr, Y, La, Ge, Al, a combination thereof, or the like.

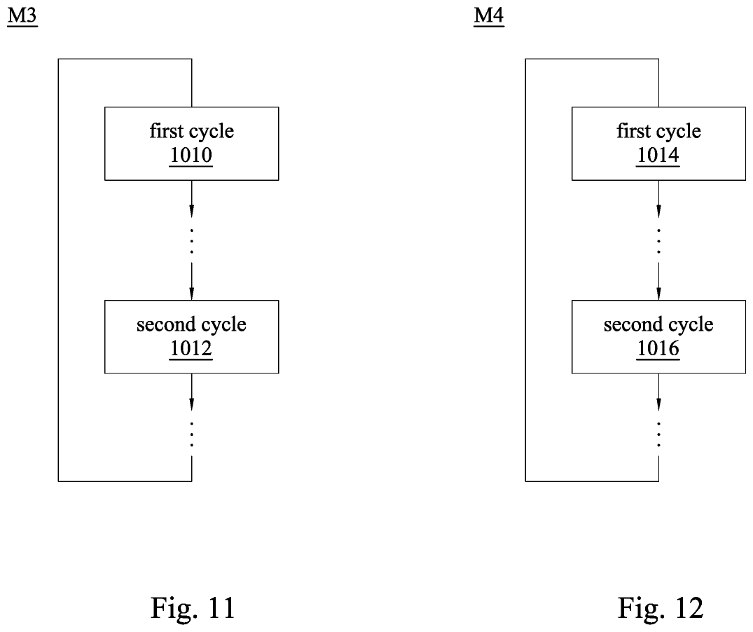

Reference is made to FIGS. 3A and 11. In some embodiments, the ferroelectric layer 102 may be formed by a method M3. The method M3 is similar to the method M1, except for the second cycle 1012 including igniting a plasma from the oxidant. That is, the method M3 may be a plasma enhanced ALD (PEALD). The plasma may be generated by RF inductive coupling to the oxidant. In some other embodiments, the oxidant in the second cycles 1012 may be oxygen or the like.

Reference is made to FIGS. 3D and 12. In some embodiments, the ferroelectric layer 102c may be formed by a method M4. The method M4 is similar to the method M2, except for the second cycle 1016 including igniting a plasma from the oxidant. That is, the method M4 may be a plasma enhanced ALD (PEALD). The plasma may be generated by RF inductive coupling to the oxidant. In some other embodiments, the oxidant in the second cycles 1016 may be oxygen or the like.

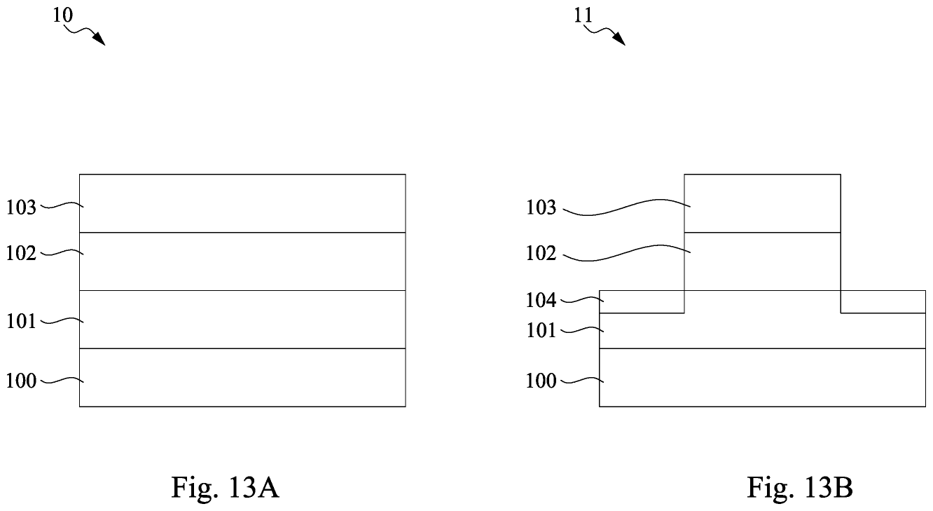

Reference is made to FIG. 13A. In some embodiments, a top electrode layer 103 is formed on the ferroelectric layer 102. In some embodiments, the top electrode layer 103 is a conductive layer, such as a metal layer including Ti, TiN, TiAl, TiAlN, W, WN, or the like. The top electrode layer 103 may be formed using ALD, sputter, or the like.

FIG. 13B is a cross-sectional view of a semiconductor device 11 in accordance with some embodiments. Reference is made to FIG. 13B. In some other embodiments, a stack of the ferroelectric layer 102 and the top electrode layer 103 may be patterned using suitable lithography and dry etching techniques. Next, portions of the semiconductor layer 101 may be doped with an n-type dopant or p-type dopants and serve as source/drain regions 104. A portion of the semiconductor layer 101 between the source/drain regions 104 may be referred to as a channel region. The opposing source/drain regions 104 are laterally separated by the channel region. A flow of carriers through the channel region is controlled by a voltage applied to the top electrode layer 103. In FIG. 13B, the substrate 100, the semiconductor layer 101, the ferroelectric layer 102 and the top electrode layer 103 can be referred to as a field effect transistor (FET) devices or a planar FET. The top electrode layer 103 acts as a gate.

In some embodiments, for straining effect or other performance enhancement, the source/drain regions 104 may be formed by epitaxy growth of different semiconductor materials. For example, the semiconductor layer 101 is recessed by etching, and a semiconductor material is epitaxially grown on the recessed region with in-situ doping to form the source/drain regions 104.

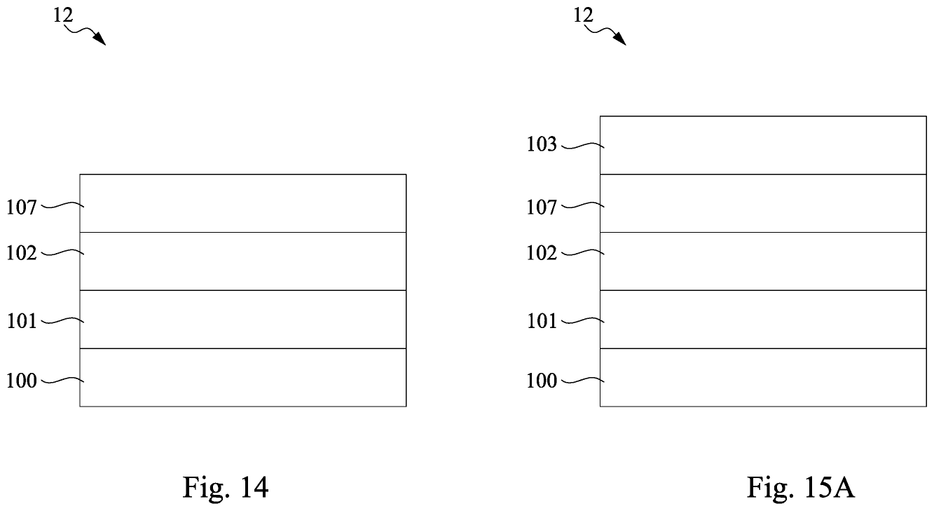

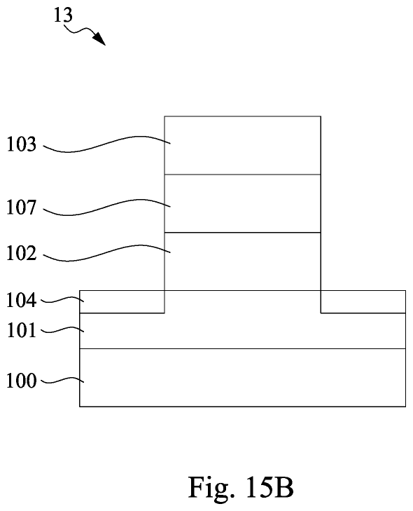

FIGS. 14 and 15A are cross-sectional views of forming an epitaxial structure 12 in accordance with some embodiments. FIG. 14 illustrates the resulting structure after the ferroelectric layer 102 is formed on the semiconductor layer 101 as discussed previously with regard to FIG. 3A. Reference is made to FIG. 14. In some embodiments, a dielectric layer 107 is formed on the ferroelectric layer 102 using such as ALD, CVD, PVD, or the like. The dielectric layer 107 and the ferroelectric layer 102 have different materials. For example, the dielectric layer 107 and the ferroelectric layer 102 may include different dielectric constants. The dielectric layer 107 is configured to achieve a desired tuning range for negative capacitance matching, which will be discussed in greater detail. In some embodiments, the dielectric layer includes Al₂O₃, HfO₂, ZrO₂, TiO₂, Ta₂O₅, Y₂O₃, SiO₂, SiCN, or Si₃N₄, or the like. In some embodiments, the dielectric layer 107 has a thickness in a range from about 0.1 nm to about 20 nm.

Next, a top electrode layer 103 is formed on the dielectric layer 107. The top electrode layer 103 is similar to the top electrode layer 103 in FIG. 13A in terms of composition and formation method, and thus the description thereof is omitted herein. The resulting structure is shown in FIG. 15A.

FIG. 15B is a cross-sectional view of a semiconductor device 13 in accordance with some embodiments. Reference is made to FIG. 15B. In some other embodiments, a stack of the ferroelectric layer 102, the dielectric layer 107 and the top electrode layer 103 may be patterned using suitable lithography and dry etching techniques. Next, portions of the semiconductor layer 101 may be doped with an n-type dopant or p-type dopants and serve as source/drain regions 104. A portion of the semiconductor layer 101 between the source/drain regions 104 may be referred to as a channel region. The opposing source/drain regions 104 are laterally separated by the channel region. A flow of carriers through the channel region is controlled by a voltage applied to the top electrode layer 103. In FIG. 15B, the substrate 100, the semiconductor layer 101, the ferroelectric layer 102 and the top electrode layer 103 can be referred to as a field effect transistor (FET) devices or a planar FET, and can be referred to as a negative capacitance field effect transistor (NCFET). The top electrode layer 103 acts as a gate.

The presence of the dielectric layer 107 may offer an addition degree of freedom in tuning the negative capacitance, For example, the capacitance of the NCFET may be adjusted based on factors such as thickness or material composition of the dielectric layer 107. To determine the capacitance of the NCFET, the dielectric layer 107 and the ferroelectric layer 102 may be referred to as two “capacitors” connected in series, as shown in Equation 1:

1/C_{Total}=1/C₁+1/C₂ Equation 1

where C_{Total} is a total capacitance of the NCFET, 1/C₁ is a capacitance provided by the dielectric layer 107, and 1/C₂ is a capacitance provide by the ferroelectric layer 102. The dielectric layer 107 provides positive capacitance, and the ferroelectric layer 102 provides negative capacitance.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that by forming a ferroelectric layer on a single crystal underlayer, the ferroelectric layer can have a low lattice misfit at an interface between the ferroelectric layer and the single crystal underlayer. Another advantage is that the ferroelectric layer can be single crystalline or very close to single crystalline (i.e., greater than about 80% crystallinity). Yet another is that the ferroelectric layer can have high remnant polarization and high uniformity, in which the high uniformity is important for integrated circuit applications.

In some embodiments, a device includes a substrate, a semiconductor layer and a ferroelectric layer. The semiconductor layer is over the substrate. The semiconductor layer is a single crystal silicon layer or a single crystal germanium layer. The ferroelectric layer is over the semiconductor layer. The ferroelectric layer is in physical contact with the semiconductor layer and has an orthorhombic phase. In some embodiments, the ferroelectric layer has a supper lattice structure made of alternately stacked first oxide films and second oxide films, and the first oxide films have a composition different from a composition of the second oxide films. In some embodiments, the ferroelectric layer is made of a plurality of first oxide films and a plurality of second oxide films, and the first oxide films have a composition different from a composition of the second oxide films. In some embodiments, a number of the plurality of first oxide films is greater than a number of the plurality of second oxide films. In some embodiments, the plurality of first oxide films includes hafnium oxide. In some embodiments, the plurality of second oxide films is made of one or more oxide materials including Zr, Si, Sr, Y, La, Ge, Al, or a combination thereof.

In some embodiments, a method of forming a device includes the following steps. An underlayer is formed over a support substrate. The underlayer is a single crystal layer. In some embodiments, an atomic layer deposition process is performed to form a ferroelectric layer over the underlayer. The ferroelectric layer has an orthorhombic phase. The electrode layer is formed over the ferroelectric layer.

In some embodiments, performing the atomic layer deposition process comprises the following steps. One or more first cycles are performed to form a first oxide film. One or more second cycles are performed to form a second oxide film. The first oxide film has a composition different from a composition of the second oxide film. In some embodiments, the first oxide film is hafnium oxide. In some embodiments, the first oxide film is in contact with the underlayer. In some embodiments, the method further comprises forming a dielectric layer over the ferroelectric layer, wherein the dielectric layer is Al₂O₃, HfO₂, ZrO₂, TiO₂, Ta₂O₅, Y₂O₃, SiO₂, SiCN, or Si₃N₄. In some embodiments, the dielectric layer is in contact with the first oxide film. In some embodiments, the second oxide film is zirconium oxide. In some embodiments, the second oxide film is in contact with the underlayer. In some embodiments, the method of claim further comprises forming a dielectric layer over the ferroelectric layer, wherein the dielectric layer is Al₂O₃, HfO₂, ZrO₂, TiO₂, Ta₂O₅, Y₂O₃, SiO₂, SiCN, or Si₃N₄. In some embodiments, the dielectric layer is in contact with the second oxide film. In some embodiments, the second oxide film is made of one or more oxide materials including Zr, Si, Sr, Y, La, Ge, Al, or a combination thereof. In some embodiments, the second oxide film is in contact with the underlayer.

In some embodiments, a method of forming a device includes the following steps. A single crystal layer is formed over a semiconductor substrate. A first ferroelectric material is grown over the single crystal layer. After growing the first ferroelectric material over the single crystal layer, a second ferroelectric material is grown over the first ferroelectric material, wherein the second ferroelectric material has a composition different from a composition of the first ferroelectric material, and the first ferroelectric material has a phase same as a phase of the second ferroelectric material. A conductive material is formed over the second ferroelectric material. In some embodiments, the phase of the first ferroelectric material and the phase of the second ferroelectric material are orthorhombic phase.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate;
a semiconductor layer over the substrate, wherein the semiconductor layer is a single crystal silicon layer or a single crystal germanium layer; and
a ferroelectric layer over the semiconductor layer, wherein the ferroelectric layer is in physical contact with the semiconductor layer and has an orthorhombic phase.

2. The device of claim 1, wherein the ferroelectric layer has a supper lattice structure made of alternately stacked first oxide films and second oxide films, and the first oxide films have a composition different from a composition of the second oxide films.

3. The device of claim 1, wherein the ferroelectric layer is made of a plurality of first oxide films and a plurality of second oxide films, and the first oxide films have a composition different from a composition of the second oxide films.

4. The device of claim 3, wherein a number of the plurality of first oxide films is greater than a number of the plurality of second oxide films.

5. The device of claim 3, wherein the plurality of first oxide films includes hafnium oxide.

6. The device of claim 3, wherein the plurality of second oxide films is made of one or more oxide materials including Zr, Si, Sr, Y, La, Ge, Al, or a combination thereof.

7. A method of forming a device, comprising:
forming an underlayer over a support substrate, wherein the underlayer is a single crystal layer;
performing an atomic layer deposition process to form a ferroelectric layer over the underlayer, wherein the ferroelectric layer has an orthorhombic phase; and
forming an electrode layer over the ferroelectric layer.

8. The method of claim 7, wherein performing the atomic layer deposition process comprises:
performing one or more first cycles to form a first oxide film; and
performing one or more second cycles to form a second oxide film, wherein the first oxide film has a composition different from a composition of the second oxide film.

9. The method of claim 8, wherein the first oxide film is hafnium oxide.

10. The method of claim 9, wherein the first oxide film is in contact with the underlayer.

11. The method of claim 9, further comprising:
forming a dielectric layer over the ferroelectric layer, wherein the dielectric layer is Al₂O₃, HfO₂, ZrO₂, TiO₂, Ta₂O₅, Y₂O₃, SiO₂, SiCN, or Si₃N₄.

12. The method of claim 11, wherein the dielectric layer is in contact with the first oxide film.

13. The method of claim 9, wherein the second oxide film is zirconium oxide.

14. The method of claim 9, wherein the second oxide film is in contact with the underlayer.

15. The method of claim 14, further comprising:
forming a dielectric layer over the ferroelectric layer, wherein the dielectric layer is Al₂O₃, HfO₂, ZrO₂, TiO₂, Ta₂O₅, Y₂O₃, SiO₂, SiCN, or Si₃N₄.

16. The method of claim 15, wherein the dielectric layer is in contact with the second oxide film.

17. The method of claim 9, wherein the second oxide film is made of one or more oxide materials including Zr, Si, Sr, Y, La, Ge, Al, or a combination thereof.

18. The method of claim 17, wherein the second oxide film is in contact with the underlayer.

19. A method of forming a device, comprising:
forming a single crystal layer over a semiconductor substrate;
growing a first ferroelectric material over the single crystal layer;
after growing the first ferroelectric material over the single crystal layer, growing a second ferroelectric material over the first ferroelectric material, wherein the second ferroelectric material has a composition different from a composition of the first ferroelectric material, and the first ferroelectric material has a phase same as a phase of the second ferroelectric material; and
forming a conductive material over the second ferroelectric material.

20. The method of claim 19, wherein the phase of the first ferroelectric material and the phase of the second ferroelectric material are orthorhombic phase.
